(19) United States
(12) Patent Application Publication
(10) Pub. No.: US 2026/0304883 A1
(43) Pub. Date: Oct. 1, 2026

(54) METHOD FOR FABRICATING NMOS HIGH-K METAL GATE AND PMOS HIGH-K METAL GATE

(71) Applicant: Huahong Integrated Circuit(Chengdu) Corporation, Chengdu City (CN)

(72) Inventors: Xiaofeng QU, Chengdu City (CN); Renhui XU, Chengdu City (CN); Kouhua SUN, Chengdu City (CN)

(73) Assignee: Huahong Integrated Circuit(Chengdu) Corporation, Chengdu City (CN)

(21) Appl. No.: 19/567,858

(22) Filed: Mar. 16, 2026

(30) Foreign Application Priority Data
Mar. 31, 2025 (CN) 202510393020.8

(51) Int. Cl. H10D 64/01; H10P 76/40

(52) U.S. Cl. CPC H10D 64/017; H10D 64/01318; H10D 64/01324; H10P 76/405

(57) ABSTRACT

The present disclosure discloses a method for fabricating an NMOS high-k metal gate and a PMOS high-k metal gate. In an HKMG N/P split process, boron (B) implantation and energy control are first performed on dummy polysilicon in an NMOS gate region of a gate stack. Subsequently, by utilizing the high etch selectivity of the etching solution toward B-doped dummy polysilicon, wet etching is performed to remove the dummy polysilicon in the PMOS gate region of the gate stack. After forming a PMOS metal gate structure, dry etching is then performed to remove the B-doped dummy polysilicon in the NMOS gate region of the gate stack. This fabrication method, during the process of achieving NFET and PFET separation, prevents undercutting of the dummy polysilicon in the NMOS gate region, optimizing the profile at the NFET/PFET boundary.

### CROSS-REFERENCE TO RELATED APPLICATIONS

This application claims priority to Chinese patent application No. 2025103930208, filed on Mar. 31, 2025, the disclosure of which is incorporated herein by reference in its entirety.

### TECHNICAL FIELD

The present disclosure relates to the field of semiconductor manufacturing technology, and particularly, to a method for fabricating an NMOS high-k metal gate and a PMOS high-k metal gate.

### BACKGROUND

In the HKMG (high-k gate dielectric layer and metal gate) process at the 28 nm technology node, within the N/P separated HKMG fabrication flow, the NMOS metal gate (NMG) and the PMOS metal gate (PMG) are fabricated separately (with the PMOS metal gate being formed first, followed by the NMOS metal gate). The NDPR (N Dummy Poly Remove, i.e., NMOS dummy polysilicon removal) step requires that the N dummy poly (NMOS dummy polysilicon) be completely removed without damaging the PMOS metal gate (PMG).

In the existing 28 nm dummy poly removal processes, forming the NFET and PFET in separate steps allows for more precise control of the gate voltage and prevents mutual interference. However, during the PDPR (P Dummy Poly Remove, i.e., PMOS dummy polysilicon removal) dry etching process, it is necessary to ensure complete removal of the dummy polysilicon while minimizing damage to the underlying TiN layer. Consequently, the physical bombardment on the bottom layer must be reduced during etching. This reduction leads to undercutting of the dummy polysilicon in the NMOS gate region (as indicated by the dotted line in FIG. 1), adversely affecting the profile at the N/P boundary. Subsequently, during the NDPR (N Dummy Poly Remove) wet etching step, this undercut further increases the difficulty of removing the dummy polysilicon at the bottom.

### SUMMARY

The technical problem to be solved by the present disclosure is to provide a method for fabricating an NMOS high-k metal gate and a PMOS high-k metal gate. During the process of achieving NFET and PFET separation, this method enables the formation of vertical sidewalls of the boron-doped dummy polysilicon in the NMOS gate region of the gate stack region, thereby optimizing the profile at the NFET/PFET interface and improving the electrical performance of the device.

In order to solve the technical problem, the present disclosure provides a method for fabricating an NMOS high-k metal gate and a PMOS high-k metal gate, including the following steps:
S1: providing a substrate 10, wherein a gate stack region is formed on the substrate 10;
the gate stack region includes a high-k layer 11 formed on the substrate 10, and a dummy polysilicon layer 12 formed on the high-k layer;
S2: forming a first bottom anti-reflective coating 14 over a wafer;
S3: coating a first photoresist layer 15 over the bottom anti-reflective coating 14, and performing a lithography process to expose the first bottom anti-reflective coating 14 on an NMOS gate region of the gate stack region, while retaining the first photoresist layer 15 on a PMOS gate region of the gate stack region;
S4: performing etching to remove the first bottom anti-reflective coating 14 on the NMOS gate region of the gate stack region, stopping on the dummy polysilicon layer 12 of the NMOS gate region of the gate stack region;
S5: performing boron ion implantation to dope the dummy polysilicon layer 12 of the NMOS gate region of the gate stack region with boron ions;
S6: removing the first photoresist layer 15 and the first bottom anti-reflective coating 14 from the wafer;
S7: performing wet etching sequentially using diluted hydrofluoric acid and ammonia to remove the dummy polysilicon layer 12 of the PMOS gate region of the gate stack region, stopping on the high-k layer 11;
S8: forming a PMOS metal gate structure 70 on the high-k layer 11 within the PMOS gate region of the gate stack region;
S9: forming a barrier layer 80 over the wafer;
S10: coating a second photoresist layer 19 over the barrier layer 80, performing a lithography process to expose the barrier layer 80 on the NMOS gate region of the gate stack region, while retaining the second photoresist layer 19 on the PMOS gate region of the gate stack region;
S11: performing etching by using the second photoresist layer 19 as a mask to remove the barrier layer 80 on the NMOS gate region of the gate stack region, stopping on the dummy polysilicon layer 12 of the NMOS gate region of the gate stack region;
S12: performing dry etching to remove the dummy polysilicon layer 12 of the NMOS gate region of the gate stack region, stopping on the high-k layer 11;
S13: removing the second photoresist layer 19 and the barrier layer 80 from the wafer; and
S14: forming an NMOS metal gate structure on the high-k layer 11 of the NMOS gate region of the gate stack region.

Preferably, a spacer 13 is formed surrounding the gate stack region.

Preferably, the spacer is SiN.

Preferably, an SiO isolation region is formed surrounding the spacer 13.

Preferably, in step S5, a dose of the boron ion implantation is greater than 1 e15^{cm-2}.

Preferably, in step S5, an energy of the boron ion implantation is in a range from 1 keV to 6 keV, performed in a single step or multiple steps.

Preferably, in step S9, the barrier layer 80 includes a TiN layer 81, a silicon oxide layer 82, and a second bottom anti-reflective coating 83 sequentially stacked from bottom to top.

Preferably, a primary material of the first bottom anti-reflective coating 14 and the second bottom anti-reflective coating 83 is organosiloxane or a high-carbon-content polymer.

Preferably, in step S8, the PMOS metal gate structure 70 includes a U-shaped PMOS work function layer 71 and an PMOS metal gate layer 75;
the U-shaped PMOS work function layer 71 has a bottom formed on the high-k layer 11 within the PMOS gate region of the gate stack region, and sidewalls respectively covering the spacer 13 on the PMOS gate region side of the gate stack region and the PMOS gate region side of the dummy polysilicon layer 12 in the NMOS gate region;
the PMOS metal gate layer 75 is formed within the U-shaped PMOS work function layer 71.

Preferably, the PMOS work function layer 71 includes a TiN outer layer 711, a TaN intermediate layer 712, and a TiN inner layer 713 sequentially formed.

Preferably, the PMOS metal gate layer 75 is A1.

Preferably, in step S13, a process for forming the NMOS metal gate structure is the same as the process for forming the PMOS metal gate structure 70 in step S8;
in step S13, the NMOS metal gate structure includes a U-shaped NMOS work function layer and an NMOS metal gate layer;
the U-shaped NMOS work function layer has a bottom formed on the high-k layer 11 within the NMOS gate region of the gate stack region, and sidewalls respectively covering the spacer 13 on an NMOS gate region side of the gate stack region and a sidewall of the U-shaped PMOS work function layer 71 in the PMOS gate region proximate to the NMOS gate region;
the NMOS metal gate layer is formed within the U-shaped NMOS work function layer.

Preferably, in step S7, a ratio of H₂O to HF in the diluted hydrofluoric acid is in a range from 100:1 to 2000:1, and a ratio of NH₄OH to H₂O in the ammonia is in a range from 1:2 to 1:10.

Preferably, the high-k layer 11 includes an SiO layer 111, an HfO₂/HfSiON layer 112, and a TiN layer 113 sequentially stacked from bottom to top.

In the method for fabricating the NMOS high-k metal gate and the PMOS high-k metal gate according to the present disclosure, within a 28 HKMG N/P split process, boron implantation and energy control are first performed on the dummy polysilicon (dummy poly) in the NMOS gate region of the gate stack region. Subsequently, wet etching is performed by utilizing the high etch selectivity of the etching solution (DHF+Ammonia) toward boron-doped dummy polysilicon (dummy poly), thereby removing the dummy polysilicon (dummy poly) in the PMOS gate region of the gate stack region. Following the formation of the PMOS metal gate structure 70, dry etching is then performed to remove the boron-doped dummy polysilicon (dummy poly) in the NMOS gate region of the gate stack region. This fabrication method, during the process of achieving NFET and PFET separation, prevents undercutting of the dummy polysilicon (dummy poly) in the NMOS gate region, obtaining vertical sidewalls of the B-doped dummy polysilicon (dummy poly) in the NMOS gate region of the gate stack, thereby optimizing the profile at the NFET/PFET boundary, and improving the electrical performance of the device.

### BRIEF DESCRIPTION OF THE DRAWINGS

In order to more clearly describe the technical solutions in the present disclosure, the following will briefly introduce the drawings needed in the present disclosure. It is obvious that the drawings in the following description are only some embodiments of the present disclosure. Those skilled in the art may obtain other drawings from these drawings without contributing any inventive labor.

FIG. 1 is a schematic diagram illustrating undercutting of dummy polysilicon in an NMOS region caused in an existing 28nm dummy polysilicon removal process.

FIG. 2 to FIG. 12 are cross-sectional schematic diagrams illustrating process steps of a method for fabricating an NMOS high-k metal gate and a PMOS high-k metal gate according to the present disclosure.

FIG. 13 is a schematic diagram illustrating etch selectivity of wet etchant toward boron-doped dummy polysilicon.

FIG. 14 is a schematic structural diagram of a high-k layer according to an embodiment.

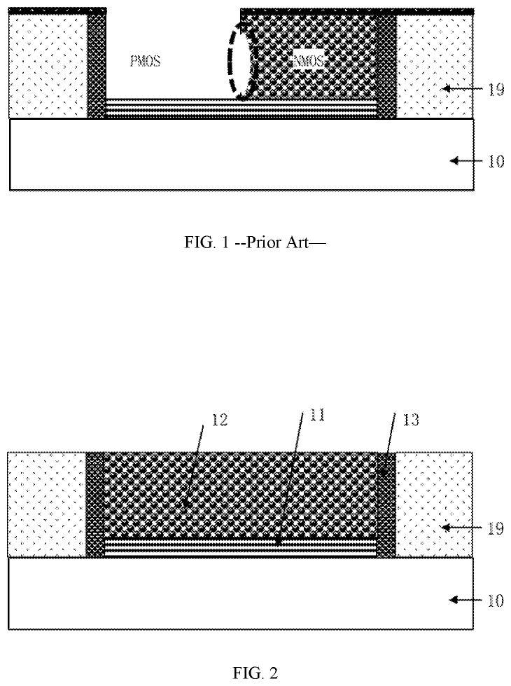

### DETAILED DESCRIPTION OF THE EMBODIMENTS

The technical solutions in the embodiments of the present disclosure will be clearly and completely described below with reference to the drawings in the embodiments of the present disclosure. Apparently, the described embodiments are merely some rather than all of the embodiments of the present disclosure. All other embodiments obtained by those skilled in the art based on the embodiments of the present disclosure without contributing any inventive labor shall still fall within the scope of protection of the present disclosure.

Words such as “first”, “second” and the like used in the present disclosure do not indicate any order, quantity, or importance, but are only intended to distinguish different components. Words such as “comprising” or “including” refer to a component or object that appears before the word, including those listed after the word and their equivalents, without excluding other components or objects. Words like “connecting” or “connected” are not limited to physical or mechanical connections, but may include electrical connections, whether direct or indirect. “Up”, “down”, “left”, “right”, and the like are only intended to represent relative positional relationships. When the absolute position of a described object changes, the relative positional relationship may also change correspondingly.

It is to be understood that, without conflict, the embodiments and features in the embodiments of the present disclosure may be freely combined with each other. cl Embodiment 1

A method for fabricating an NMOS high-k metal gate and a PMOS high-k metal gate, as shown in FIG. 2 to FIG. 12, includes the following steps:
S1: providing a substrate 10, wherein a gate stack region is formed on the substrate 10;
the gate stack region includes a high-k (HK) layer 11 formed on the substrate 10, and a dummy polysilicon layer 12 formed on the high-k layer, as shown in FIG. 2;
S2: forming a first Bottom Anti-Reflective Coating (BARC) 14 over a wafer.

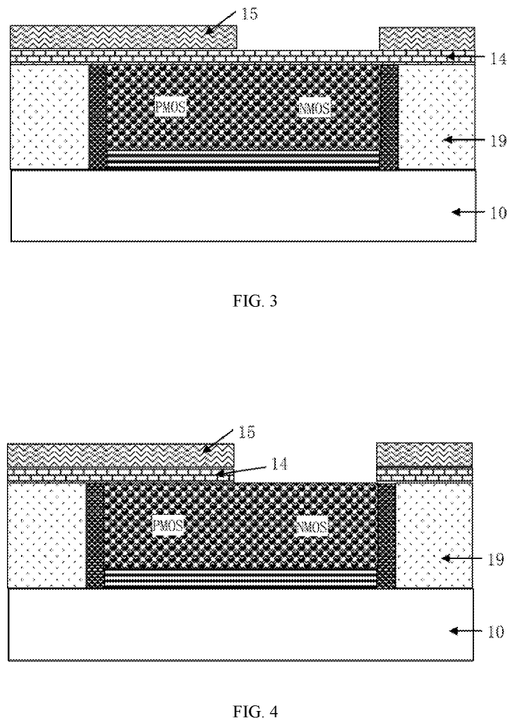

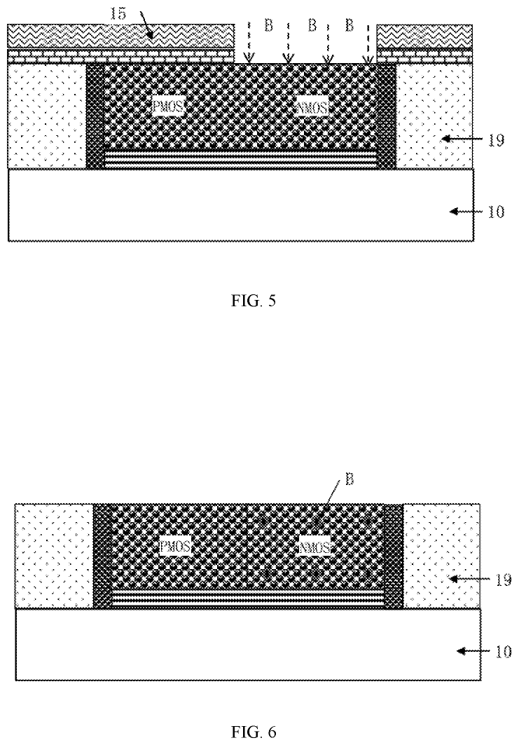

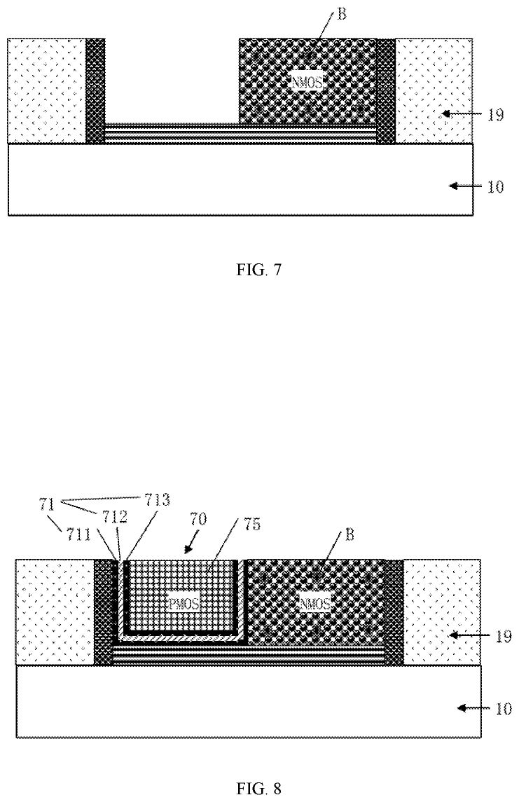

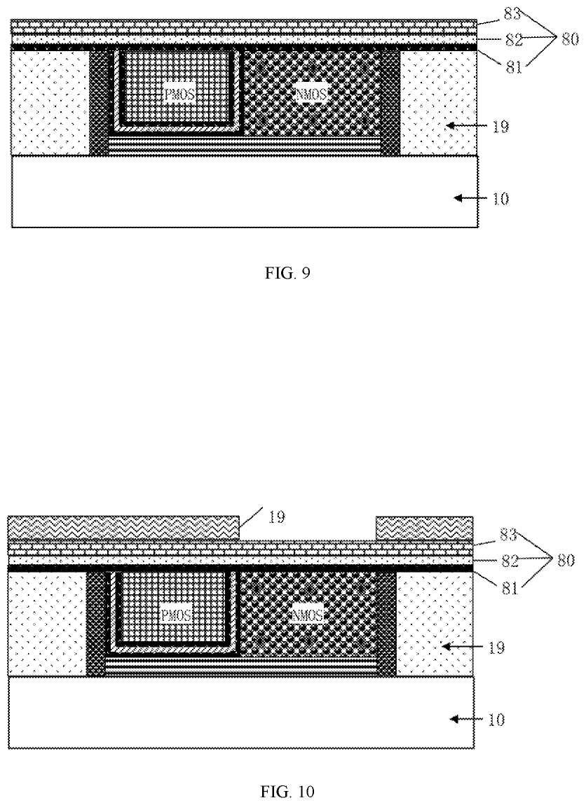

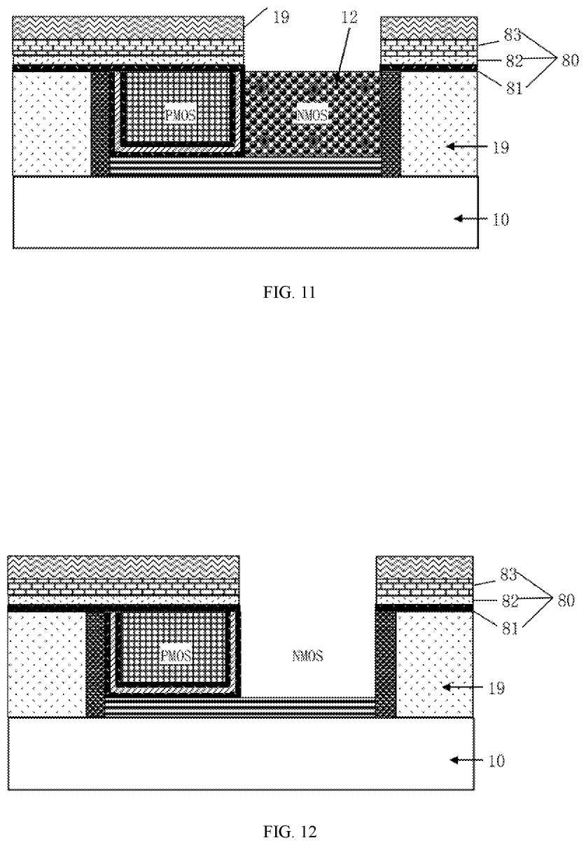

S3: coating a first photoresist layer 15 over the bottom anti-reflective coating 14, and performing a lithography process to expose the first bottom anti-reflective coating 14 on an NMOS gate region of the gate stack region, while retaining the first photoresist layer 15 on a PMOS gate region of the gate stack region, as shown in FIG. 3;
S4: performing etching to remove the first bottom anti-reflective coating 14 on the NMOS gate region of the gate stack region, stopping on the dummy polysilicon layer 12 of the NMOS gate region of the gate stack region, as shown in FIG. 4;
S5: performing boron ion implantation to dope the dummy polysilicon layer 12 of the NMOS gate region of the gate stack region with boron ions, as shown in FIG. 5;
S6: removing the first photoresist layer 15 and the first bottom anti-reflective coating 14 from the wafer, as shown in FIG. 6;
S7: performing wet etching sequentially using diluted hydrofluoric acid (DHF) and ammonia to remove the dummy polysilicon layer 12 of the PMOS gate region of the gate stack region, stopping on the high-k layer 11, as shown in FIG. 7;
S8: forming a PMOS metal gate structure 70 on the high-k layer 11 within the PMOS gate region of the gate stack region, as shown in FIG. 8;
S9: forming a barrier layer 80 over the wafer, as shown in FIG. 9;
S10: coating a second photoresist layer 19 over the barrier layer 80, performing a lithography process to expose the barrier layer 80 on the NMOS gate region of the gate stack region, while retaining the second photoresist layer 19 on the PMOS gate region of the gate stack region, as shown in FIG. 10;
S11: performing etching to remove the barrier layer 80 on the NMOS gate region of the gate stack region, stopping on the dummy polysilicon layer 12 of the NMOS gate region of the gate stack region, as shown in FIG. 11;
S12: performing dry etching to remove the dummy polysilicon layer 12 of the NMOS gate region of the gate stack region, stopping on the high-k layer 11, as shown in FIG. 12;
S13: removing the second photoresist layer 19 and the barrier layer 80 from the wafer; and
S14: forming an NMOS metal gate structure on the high-k layer 11 of the NMOS gate region of the gate stack region.

Through experiments, the applicant has discovered that the etch selectivity of the wet etchant (DHF+Ammonia) toward boron-doped dummy polysilicon increases with an increase in the boron doping dose, as shown in FIG. 13.

In the method for fabricating the NMOS high-k metal gate and the PMOS high-k metal gate according to Embodiment 1, within a 28 HKMG N/P split process, boron implantation and energy control are first performed on the dummy polysilicon (dummy poly) in the NMOS gate region of the gate stack region. Subsequently, wet etching is performed by utilizing the high etch selectivity of the etching solution (DHF+Ammonia) toward boron-doped dummy polysilicon (dummy poly), thereby removing the dummy polysilicon (dummy poly) in the PMOS gate region of the gate stack region. Following the formation of the PMOS metal gate structure 70, dry etching is then performed to remove the boron-doped dummy polysilicon (dummy poly) in the NMOS gate region of the gate stack region. This fabrication method, during the process of achieving NFET and PFET separation, prevents undercutting of the dummy polysilicon (dummy poly) in the NMOS gate region, obtaining vertical sidewalls of the B-doped dummy polysilicon (dummy poly) in the NMOS gate region of the gate stack, thereby optimizing the profile at the NFET/PFET boundary, and improving the electrical performance of the device.

### Embodiment 2

Based on the method for fabricating the NMOS high-k metal gate and the PMOS high-k metal gate according to Embodiment 1, in step S5, a dose of the boron ion implantation is greater than 1e15 cm⁻².

Preferably, in step S5, an energy of the boron ion implantation is in a range from 1 keV to 6 keV, performed in a single step or multiple steps.

### Embodiment 3

Based on the method for fabricating the NMOS high-k metal gate and the PMOS high-k metal gate according to Embodiment 1, in step S1, a spacer 13 is formed surrounding the gate stack region.

Preferably, the spacer 13 is SiN.

Preferably, an SiO isolation region is formed surrounding the spacer 13.

### Embodiment 4

Based on the method for fabricating the NMOS high-k metal gate and the PMOS high-k metal gate according to Embodiment 1, in step S8, the PMOS metal gate structure 70 includes a U-shaped PMOS work function layer 71 and an PMOS metal gate layer 75; the U-shaped PMOS work function layer 71 has a bottom formed on the high-k layer 11 within the PMOS gate region of the gate stack region, and sidewalls respectively covering the spacer 13 on the PMOS gate region side of the gate stack region and the PMOS gate region side of the dummy polysilicon layer 12 in the NMOS gate region; the PMOS metal gate layer 75 is formed within the U-shaped PMOS work function layer 71.

Preferably, the PMOS work function layer 71 includes a TiN outer layer 711, a TaN intermediate layer 712, and a TiN inner layer 713 sequentially formed.

Preferably, the PMOS metal gate layer 75 is Al.

### Embodiment 5

Based on the method for fabricating the NMOS high-k metal gate and the PMOS high-k metal gate according to Embodiment 1, in step S13, a process for forming the NMOS metal gate structure is the same as the process for forming the PMOS metal gate structure 70 in step S8;
in step S13, the NMOS metal gate structure includes a U-shaped NMOS work function layer and an NMOS metal gate layer;
the U-shaped NMOS work function layer has a bottom formed on the high-k layer 11 within the NMOS gate region of the gate stack region, and sidewalls respectively covering the spacer 13 on an NMOS gate region side of the gate stack region and a sidewall of the U-shaped PMOS work function layer 71 in the PMOS gate region proximate to the NMOS gate region;
the NMOS metal gate layer is formed within the U-shaped NMOS work function layer.

The NMOS metal gate layer is Al.

### Embodiment 6

Based on the method for fabricating the NMOS high-k metal gate and the PMOS high-k metal gate according to Embodiment 1, in step S9, the barrier layer 80 includes a TiN layer 81, a silicon oxide layer 82, and a second bottom anti-reflective coating 83 sequentially stacked from bottom to top.

Preferably, a primary material of the first bottom anti-reflective coating 14 and the second bottom anti-reflective coating 83 is organosiloxane or a high-carbon-content polymer.

Preferably, in step S7, a ratio of H₂O to HF in the diluted hydrofluoric acid is in a range from 100:1 to 2000:1, and a ratio of NH₄OH to H₂O in the ammonia is in a range from 1:2 to 1:10.

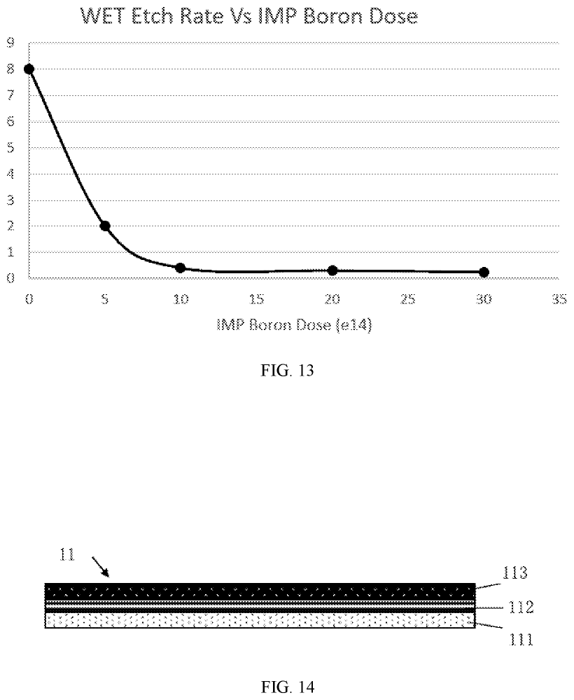

Preferably, the high-k (HK) layer 11 includes an SiO layer 111, an HfO₂/HfSiON layer 112, and a TiN layer 113 sequentially stacked from bottom to top, as shown in FIG. 14.

What are described above are only exemplary embodiments of the present disclosure, and are not intended to limit the present disclosure. Any modifications, equivalent replacements, improvements and the like made within the spirit and principle of the present disclosure shall all be included in the scope of protection of the present disclosure.

What is claimed is:

1. A method for fabricating an NMOS high-k metal gate and a PMOS high-k metal gate, comprising the following steps:
S1: providing a substrate, wherein a gate stack region is formed on the substrate;
the gate stack region comprises a high-k layer formed on the substrate, and a dummy polysilicon layer formed on the high-k layer;
S2: forming a first bottom anti-reflective coating over a wafer;
S3: coating a first photoresist layer over the bottom anti-reflective coating, and performing a lithography process to expose the first bottom anti-reflective coating on an NMOS gate region of the gate stack region, while retaining the first photoresist layer on a PMOS gate region of the gate stack region;
S4: performing etching to remove the first bottom anti-reflective coating on the NMOS gate region of the gate stack region, stopping on the dummy polysilicon layer of the NMOS gate region of the gate stack region;
S5: performing boron ion implantation to dope the dummy polysilicon layer of the NMOS gate region of the gate stack region with boron ions;
S6: removing the first photoresist layer and the first bottom anti-reflective coating from the wafer;
S7: performing wet etching sequentially using diluted hydrofluoric acid and ammonia to remove the dummy polysilicon layer of the PMOS gate region of the gate stack region, stopping on the high-k layer;
S8: forming a PMOS metal gate structure on the high-k layer within the PMOS gate region of the gate stack region;
S9: forming a barrier layer over the wafer;
S10: coating a second photoresist layer over the barrier layer, performing a lithography process to expose the barrier layer on the NMOS gate region of the gate stack region, while retaining the second photoresist layer on the PMOS gate region of the gate stack region;
S11: performing etching to remove the barrier layer on the NMOS gate region of the gate stack region, stopping on the dummy polysilicon layer of the NMOS gate region of the gate stack region;
S12: performing dry etching to remove the dummy polysilicon layer of the NMOS gate region of the gate stack region, stopping on the high-k layer;
S13: removing the second photoresist layer and the barrier layer from the wafer; and
S14: forming an NMOS metal gate structure on the high-k layer of the NMOS gate region of the gate stack region.

2. The method according to claim 1, wherein
a spacer is formed surrounding the gate stack region.

3. The method according to claim 2, wherein
the spacer is SiN.

4. The method according to claim 3, wherein
an SiO isolation region is formed surrounding the spacer.

5. The method according to claim 1, wherein
in step S5, a dose of the boron ion implantation is greater than 1e15 cm⁻².

6. The method according to claim 5, wherein
in step S 5, an energy of the boron ion implantation is in a range from 1 keV to 6 keV, performed in a single step or multiple steps.

7. The method according to claim 1, wherein
in step S9, the barrier layer comprises a TiN layer, a silicon oxide layer, and a second bottom anti-reflective coating sequentially stacked from bottom to top.

8. The method according to claim 7, wherein
a primary material of the first bottom anti-reflective coating and the second bottom anti-reflective coating is organosiloxane or a high-carbon-content polymer.

9. The method according to claim 1, wherein
in step S8, the PMOS metal gate structure comprises a U-shaped PMOS work function layer and a PMOS metal gate layer;
the U-shaped PMOS work function layer has a bottom formed on the high-k layer within the PMOS gate region of the gate stack region, and sidewalls respectively covering the spacer on the PMOS gate region side of the gate stack region and the PMOS gate region side of the dummy polysilicon layer in the NMOS gate region.
the PMOS metal gate layer is formed within the U-shaped PMOS work function layer.

10. The method according to claim 9, wherein
the PMOS work function layer comprises a TiN outer layer, a TaN intermediate layer, and a TiN inner layer sequentially formed.

11. The method according to claim 9, wherein
the PMOS metal gate layer is Al.

12. The method according to claim 9, wherein
in step S13, a process for forming the NMOS metal gate structure is the same as the process for forming the PMOS metal gate structure in step S8;
in step S13, the NMOS metal gate structure comprises a U-shaped NMOS work function layer and an NMOS metal gate layer;
the U-shaped NMOS work function layer has a bottom formed on the high-k layer within the NMOS gate region of the gate stack region, and sidewalls respectively covering the spacer on an NMOS gate region side of the gate stack region and a sidewall of the U-shaped PMOS work function layer in the PMOS gate region proximate to the NMOS gate region. the NMOS metal gate layer is formed within the U-shaped NMOS work function layer.

13. The method according to claim 1, wherein
in step S 7, a ratio of H₂O to HF in the diluted hydrofluoric acid is in a range from 100:1 to 2000:1, and a ratio of NH₄OH to H₂O in the ammonia is in a range from 1:2 to 1:10.

14. The method according to claim 1, wherein
the high-k layer comprises an SiO layer, an HfO₂/HfSiON layer, and a TiN layer sequentially stacked from bottom to top.
